(19) United States
(12) Patent Application Publication
(10) Pub. No.: US 2024/0413214 A1
(43) Pub. Date: Dec. 12, 2024

(54) SELF ALIGNED BACKSIDE CONTACT

(71) Applicant: INTERNATIONAL BUSINESS MACHINES CORPORATION, ARMONK, NY (US)

(72) Inventors: Ruilong Xie, Niskayuna, NY (US); Kisik Choi, Watervliet, NY (US); Chanro Park, Clifton Park, NY (US); Shogo Mochizuki, Mechanicville, NY (US); Julien Frougier, Albany, NY (US)

(21) Appl. No.: 18/332,785

(22) Filed: Jun. 12, 2023

(51) Int. Cl. H01L 29/417; H01L 29/06; H01L 29/423; H01L 29/775

(52) U.S. Cl. CPC H01L 29/41766; H01L 29/0673; H01L 29/42392; H01L 29/775

(57) ABSTRACT

A semiconductor structure including first source drain regions and second source drain regions arranged above a backside dielectric layer, and a buffer layer physically separating at least one of the second source drain regions from the backside dielectric layer, where at least one of the first source drain regions is in direct contact with the backside dielectric layer.

### BACKGROUND

The present invention generally relates to semiconductor structures, and more particularly to nanosheet transistor structures having self-aligned backside contacts.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include first source drain regions and second source drain regions arranged above a backside dielectric layer, and a buffer layer physically separating at least one of the second source drain regions from the backside dielectric layer, where at least one of the first source drain regions is in direct contact with the backside dielectric layer.

According to another embodiment of the present invention, a semiconductor structure is provided. The semiconductor structure may include first source drain regions and second source drain regions arranged above a backside dielectric layer, a buffer layer physically separating at least one of the second source drain regions from the backside dielectric layer, where at least one of the first source drain regions is in direct contact with the backside dielectric layer, and a bottom dielectric isolation layer physically separating nanosheet stacks from the backside dielectric layer.

According to another embodiment of the present invention, a semiconductor structure is provided. The semiconductor structure may include first source drain regions between a first set of adjacent nanosheet channels, second source drain regions between a second set of adjacent nanosheet channels, a backside dielectric layer arranged below all of the first source drain regions and the second source drain regions, and a buffer layer physically separating at least one of the second source drain regions from the backside dielectric layer, where at least one of the first source drain regions is in direct contact with the backside dielectric layer.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after forming and patterning a sacrificial gate dielectric (not shown) and sacrificial gates according to an exemplary embodiment;

FIGS. 8, 9, and 10 are cross-sectional views of the semiconductor structure after selectively removing the second sacrificial nanosheets according to an exemplary embodiment;

FIGS. 11, 12, and 13 are cross-sectional views of the semiconductor structure after forming a spacer material according to an exemplary embodiment;

FIGS. 14, 15, and 16 are cross-sectional views of the semiconductor structure after removing portions of the nanosheet stacks according to an exemplary embodiment;

FIGS. 17, 18, and 19 are cross-sectional views of the semiconductor structure after forming inner spacers according to an exemplary embodiment;

FIGS. 20, 21, and 22 are cross-sectional views of the semiconductor structure after forming a first sacrificial liner according to an exemplary embodiment;

FIGS. 23, 24, and 25 are cross-sectional views of the semiconductor structure after forming a first mask and removing portions of the first sacrificial liner according to an exemplary embodiment;

FIGS. 26, 27, and 28 are cross-sectional views of the semiconductor structure after forming first source drain regions according to an exemplary embodiment;

FIGS. 29, 30, and 31 are cross-sectional views of the semiconductor structure after removing remaining portions of the first sacrificial liner according to an exemplary embodiment;

FIGS. 32, 33, and 34 are cross-sectional views of the semiconductor structure after forming a second sacrificial liner according to an exemplary embodiment;

FIGS. 35, 36, and 37 are cross-sectional views of the semiconductor structure after forming second mask according to an exemplary embodiment;

FIGS. 38, 39, and 40 are cross-sectional views of the semiconductor structure after forming a buffer layer and second source drain regions according to an exemplary embodiment;

FIGS. 41, 42, and 43 are cross-sectional views of the semiconductor structure after removing remaining portions of the second sacrificial liner according to an exemplary embodiment;

FIGS. 44, 45, and 46 are cross-sectional views of the semiconductor structure after forming a dielectric layer, selectively removing the sacrificial gates and the first sacrificial nanosheets, forming gate structures, forming source drain contacts, forming middle-of-line and back-end-of-line and securing a carrier wafer according to an exemplary embodiment;

FIGS. 47 48, and 49 are cross-sectional views of the semiconductor structure after flipping the assembly and recessing the substrate according to an exemplary embodiment;

FIGS. 50 51, and 52 are cross-sectional views of the semiconductor structure after removing remaining portions of the substrate according to an exemplary embodiment;

FIGS. 53, 54, and 55 are cross-sectional views of the semiconductor structure after forming a backside dielectric layer according to an exemplary embodiment;

FIGS. 56, 57, and 58 are cross-sectional views of the semiconductor structure after forming a second mask and backside contact trenches according to an exemplary embodiment;

FIGS. 59, 60, and 61 are cross-sectional views of the semiconductor structure after recessing or removing the buffer layer according to an exemplary embodiment; and

FIGS. 62, 63, and 64 are cross-sectional views of the semiconductor structure after forming backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional placeholder fabrication techniques run the risk of causing damage to the gate hard mask, resulting spacer loss and epi nodules. The placeholder-based backside contact also involves high aspect ratio patterning, which increases risk of gate bending or collapse. Therefore, it is desired to form backside contacts without need of creating deep placeholders under source drain regions.

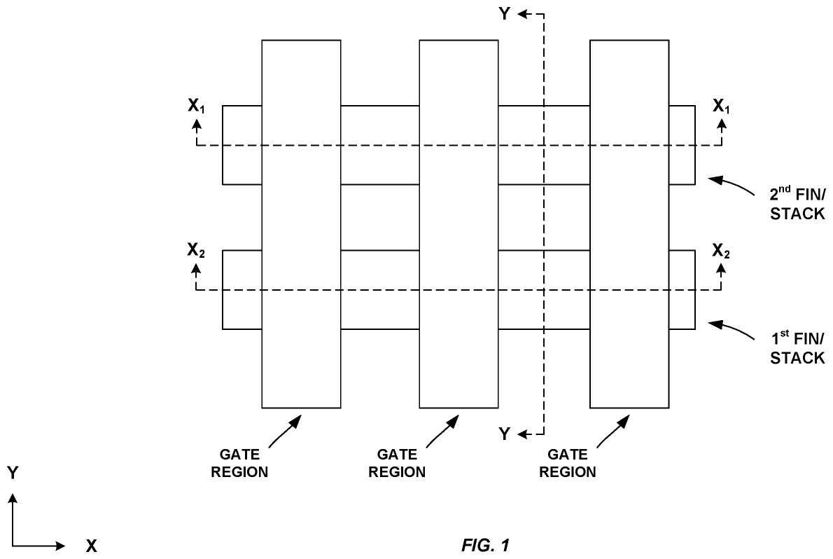

The present invention generally relates to semiconductor structures, and more particularly to nanosheet transistor structures having self-aligned backside contacts. More specifically, the nanosheet transistor structures and associated method disclosed herein enable a novel solution for providing self-aligned backside device contacts without the need of forming deep placeholders under source drain regions. Exemplary embodiments of nanosheet transistor structures having self-aligned backside contacts are described in detail below by referring to the accompanying drawings in FIGS. 1 to 64. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows a first fin/stack, a second fin/stack, and a gate region situated perpendicular to the fins/stacks. FIGS. 1-64 represent cross section views oriented as indicated in FIG. 1

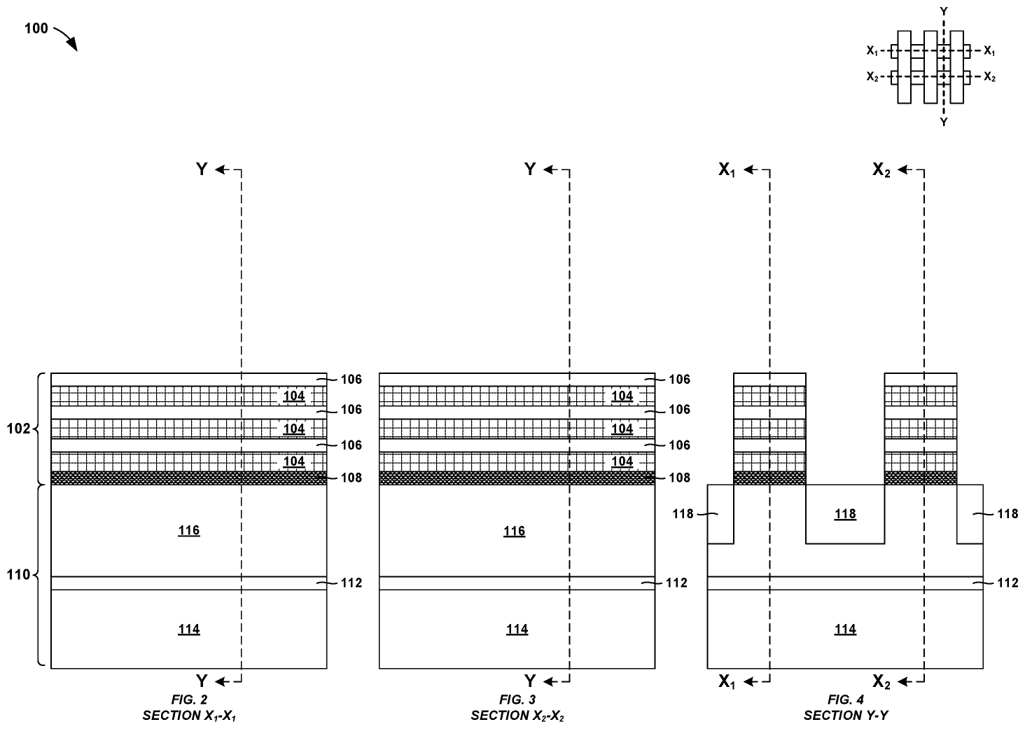

Referring now to FIGS. 2, 3, and 4, a structure 100 is shown during an intermediate step of a method of fabricating a stacked transistor structure according to an embodiment of the invention. FIG. 2 depicts a cross-sectional view of the structure 100 shown in FIG. 4 taken along line X₁-X₁, FIG. 3 depicts a cross-sectional view of the structure 100 shown in FIG. 4 taken along line X₂-X₂, and FIG. 3 depicts a cross-sectional view of the structure 100 shown in FIGS. 2 and 3 taken along line Y-Y.

The structure 100 illustrated in FIGS. 2-3 includes nanosheet stacks 102, or fins, formed from an alternating series of first silicon germanium (SiGe) sacrificial nanosheets 104 (hereinafter “first sacrificial nanosheets 104”), silicon (Si) channel nanosheets 106 (hereinafter “channel nanosheets 106”), and second silicon germanium (SiGe) sacrificial nanosheets 108 (hereinafter “second sacrificial nanosheets 108”), as illustrated. The nanosheet stacks 102 are formed on a silicon substrate 110. Although only a limited number of nanosheet stacks 102 and nanosheet layers are shown, one or more additional nanosheet stacks and/or nanosheets can optionally be epitaxially grown in an alternating fashion, and the properties of any additional nanosheets are the same as the corresponding nanosheets described herein.

According to embodiments of the present disclosure, the first sacrificial nanosheets 104 have a different germanium concentration than the second sacrificial nanosheets 108. In at least one embodiment, the second sacrificial nanosheets 108 have a higher germanium concentration than the first sacrificial nanosheets 104. More specifically, for example, the second sacrificial nanosheets 108 may have a germanium concentration ranging from about 45 to about 70 percent, while the first sacrificial nanosheets 104 may have a germanium concentration ranging from about 15 to about 40 percent. In all cases, the different germanium concentrations are designed to allow for each of the first sacrificial nanosheets 104 and the second sacrificial nanosheets 108 to be etched selective to one another. As such, other germanium concentrations are explicitly contemplated.

In one or more embodiments, the nanosheet stacks 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, in at least one embodiment, each nanosheet stack 102 includes channel nanosheets 106 which are doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 110 may be a layered semiconductor such as a silicon-on-insulator or SiGe-on-insulator, where an etch stop layer 112, separates a base substrate 114 from a top semiconductor layer 116. Unlike conventional layered semiconductor substrates, the etch stop layer 112 of the substrate 110 may include any material which affects the desired etch selectivity during subsequent processing. For example, the etch stop layer 112 may be a conventional buried oxide layer, or it may be a silicon germanium layer with a specific germanium concentration. In practice, the etch stop layer 112 will function as an etch stop layer and can be composed of any material which supports that function.

In the present embodiment, both the base substrate 114 and the top semiconductor layer 116 may be any bulk substrate made from any of several known semiconductor materials such as, for example, silicon, germanium, silicon-germanium alloy, and compound (e.g. III-V and II-VI) semiconductor materials. For example, both the base substrate 114 and the top semiconductor layer 116 may be made from silicon. Additionally, both the etch stop layer 112 and the base substrate 114 are sacrificial and will not remain in the final structure.

Known processing techniques have been applied to the alternating layers to form the nanosheet stacks 102 shown. For example, the known processing techniques can include the formation of hard masks (not shown) over the topmost layer of the nanosheet stacks 102. The hard masks can be formed by first depositing the hard mask material (for example silicon nitride) onto the topmost layer of the nanosheet stack 102 using, for example, chemical vapor deposition (CVD), plasma enhanced CVD (PECVD) or any suitable technique for dielectric deposition that does not induce a physical or chemical change to the topmost layer of the nanosheet stack 102. According to an exemplary embodiment, the hard mask material is deposited onto the channel nanosheets 106 at the top of the nanosheet stack 102 and then patterned into a plurality of the individual hard masks. Patterning the hard mask is commensurate with a desired footprint and location of the nanosheet stacks 102 shown in FIG. 4, which will subsequently be used to form the channel regions of semiconductor devices disclosed herein. According to an exemplary embodiment, RIE is used to transfer the hard mask pattern into the alternating layers to form the nanosheet stacks 102, and into the substrate 110, as shown.

Next, shallow trench isolation regions 118 (hereinafter “STI regions 118”) are formed according to known techniques. The STI regions 118 are formed at the bottom of trenches in the substrate 110 formed during patterning of the nanosheet stacks 102. Specifically, a dielectric material is deposited at the bottom of trenches in the substrate 110 to isolate adjacent devices from one another according to known techniques. The STI regions 118 may be formed from any appropriate dielectric material including, for example, silicon oxide (SiOₓ) or silicon nitride (SiₓN_{y}).

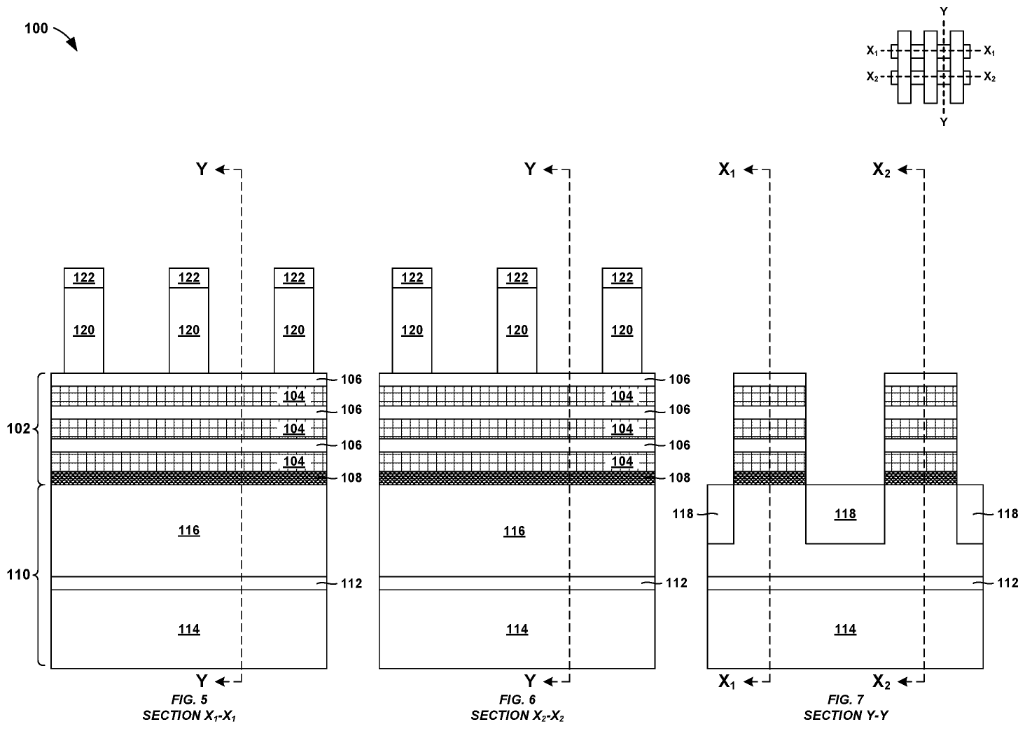

Referring now to FIGS. 5, 6, and 7, the structure 100 is shown after forming and patterning a sacrificial gate dielectric (not shown) and sacrificial gates 120 according to an embodiment of the invention. FIG. 5 depicts a cross-sectional view of the structure 100 shown in FIG. 7 taken along line X₁-X₁, FIG. 6 depicts a cross-sectional view of the structure 100 shown in FIG. 7 taken along line X₂-X₂, and FIG. 7 depicts a cross-sectional view of the structure 100 shown in FIGS. 5 and 6 taken along line Y-Y.

The sacrificial gate dielectric is deposited directly on exposed surfaces of the structure 100 according to known techniques. Specifically, for example, a relatively thin layer of silicon oxide (SiO2) is first conformally deposited over and around the nanosheet stacks 102, as illustrated.

The sacrificial gates 120 are blanket deposited over and around the nanosheet stacks 102 according to known techniques. Specifically, for example, a relatively thick layer of amorphous silicon is blanket deposited directly on the sacrificial gate dielectric, as illustrated. In this manner, both the sacrificial gate dielectric and the sacrificial gates 120 completely cover the nanosheet stacks 102, as illustrated.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a gate hard mask 122 is formed over the structure 100. The gate hard mask 122 defines gate regions of individual devices. According to an exemplary embodiment, the gate hard mask 122 material is deposited onto the sacrificial gates 120 and then patterned into a plurality of individual gate hard mask 122. Next, the pattern created by the individual gate hard mask 122 is transferred into the sacrificial gate dielectric and the sacrificial gates 120. Specifically, portions of sacrificial gate dielectric and the sacrificial gates 120 are etched or removed selective to the gate hard mask 122, as illustrated. The portions of the sacrificial gate dielectric and the sacrificial gates can be removed using a silicon RIE process.

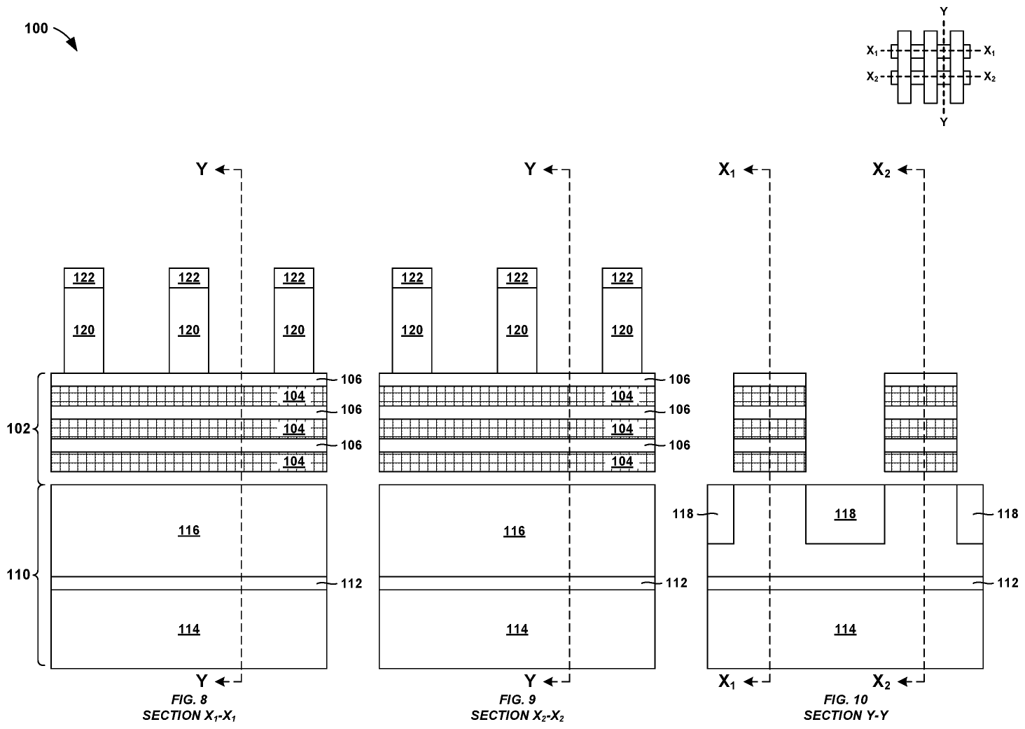

Referring now to FIGS. 8, 9, and 10, the structure 100 is shown after selectively removing the second sacrificial nanosheets 108 according to an embodiment of the invention. FIG. 8 depicts a cross-sectional view of the structure 100 shown in FIG. 10 taken along line X₁-X₁, FIG. 9 depicts a cross-sectional view of the structure 100 shown in FIG. 10 taken along line X₂-X₂, and FIG. 10 depicts a cross-sectional view of the structure 100 shown in FIGS. 8 and 9 taken along line Y-Y.

More specifically, the second sacrificial nanosheets 108 are etched and removed selective to the first sacrificial nanosheets 104 and/or the channel nanosheets 106 according to known techniques. Doing so is made possible by the different concentrations of germanium. In this case, the layers with the relatively higher germanium concentration are removed selective to layers with the relatively lower germanium concentrations.

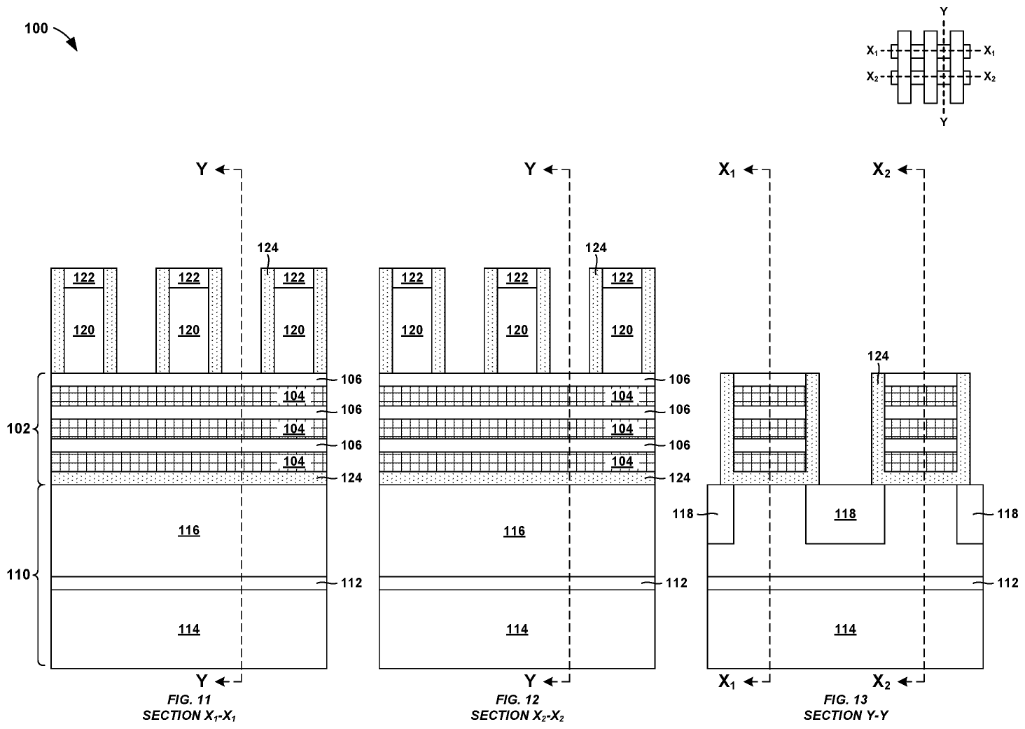

Referring now to FIGS. 11, 12, and 13, the structure 100 is shown after forming a spacer material 124 according to an embodiment of the invention. FIG. 11 depicts a cross-sectional view of the structure 100 shown in FIG. 13 taken along line X₁-X₁, FIG. 12 depicts a cross-sectional view of the structure 100 shown in FIG. 13 taken along line X₂-X₂, and FIG. 13 depicts a cross-sectional view of the structure 100 shown in FIGS. 11 and 12 along line Y-Y.

The spacer material 124 is deposited directly on exposed surfaces of the structure 100 according to known techniques. Specifically, for example, a relatively thin layer of silicon nitride is conformally deposited as illustrated. In some embodiments, for example, the spacer material 124 may be composed of SiN, SiBCN, SiOCN, SiOC, or any other combination of low-k materials. The term “low-k” as used throughout the present application denotes a dielectric material that has a dielectric constant of less than 4.0. According to embodiments of the present disclosure, the spacer material 124 substantially fills the space created by removing the second sacrificial nanosheets 108, and functions to isolate the nanosheet stacks 102 from the substrate 110. Further, according to embodiments of the present disclosure, the spacer material 124 substantially covers exposed vertical sidewalls of the nanosheet stacks 102 and exposed vertical sidewalls of the sacrificial gate 120, as illustrated in FIG. 13.

After deposition, in at least an embodiment, portions of the spacer material 124 are selectively removed or etched from horizontal surfaces according to known techniques. Doing so will generally expose the nanosheet stacks 102 and the STI regions 118, as illustrated.

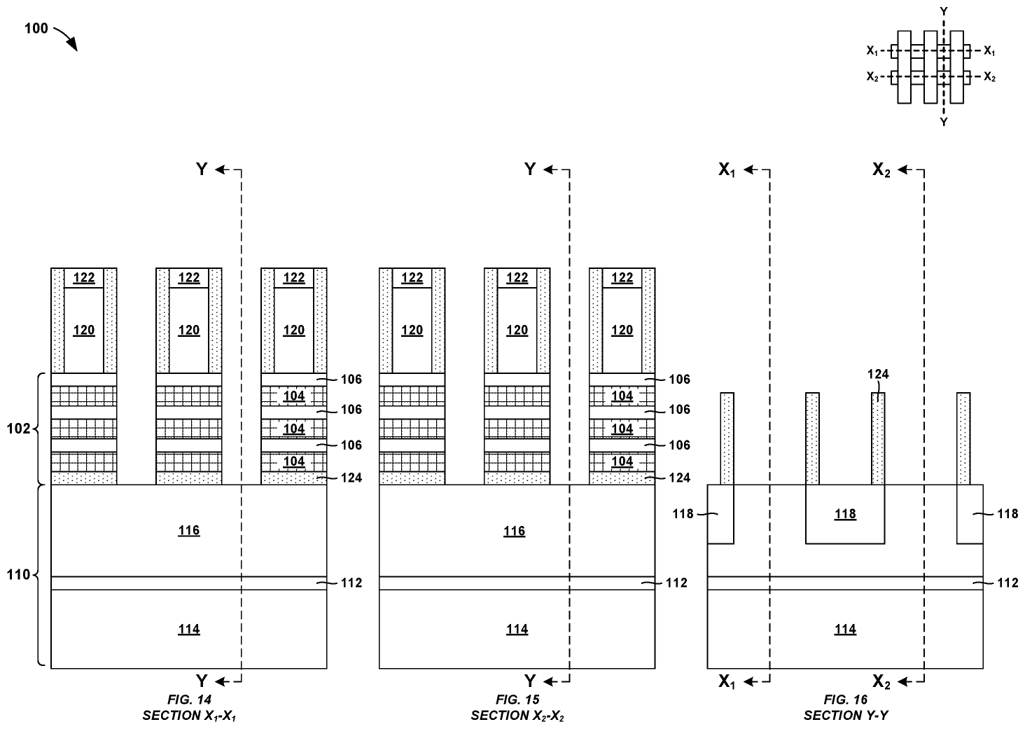

Referring now to FIGS. 14, 15, and 16, the structure 100 is shown after removing portions of the nanosheet stacks 102 according to an embodiment of the invention. FIG. 14 depicts a cross-sectional view of the structure 100 shown in FIG. 16 taken along line X₁-X₁, FIG. 15 depicts a cross-sectional view of the structure 100 shown in FIG. 16 taken along line X₂-X₂, and FIG. 16 depicts a cross-sectional view of the structure 100 shown in FIGS. 14 and 15 taken along line Y-Y.

Portions of the nanosheet stacks 102 are etched and removed from between the sacrificial gates 120 according to known techniques. Specifically, the pattern created by the individual gate hard mask 122 and the spacer material 124 is transferred into the nanosheet stacks 102. In doing so, portions of the first sacrificial nanosheets 104, and the channel nanosheets 106, are removed selective to the spacer material 124, as illustrated.

In an embodiment, portions of the nanosheet stacks 102 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until the substrate 110 is exposed, as illustrated.

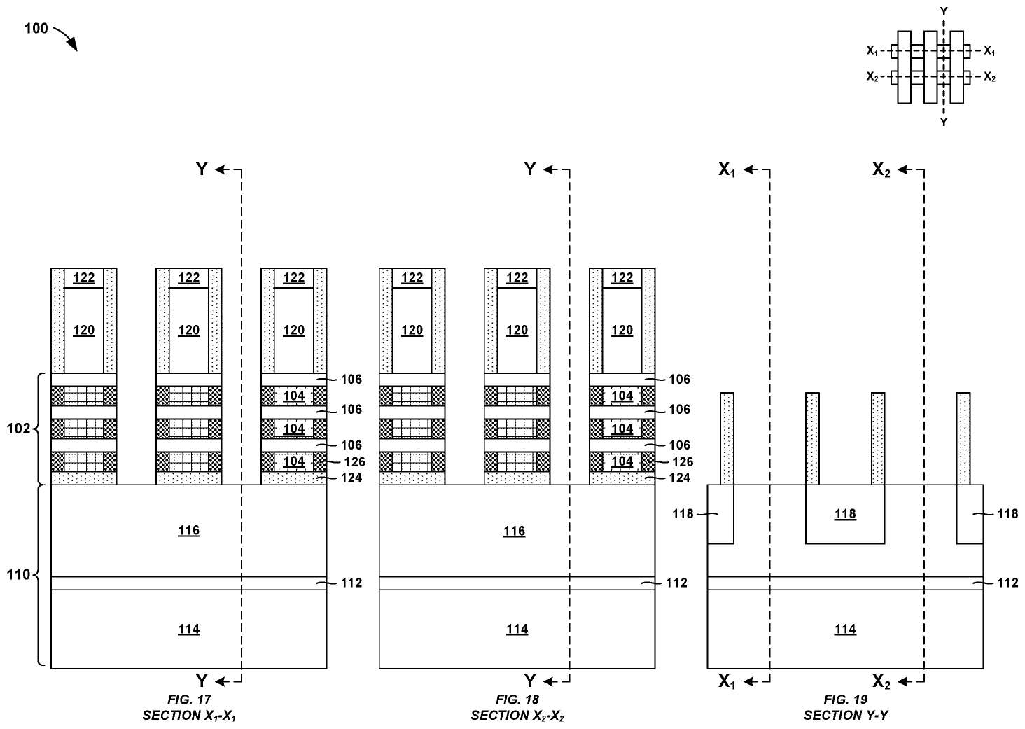

Referring now to FIGS. 17, 18, and 19, the structure 100 is shown after forming inner spacers 126 according to an embodiment of the invention. FIG. 17 depicts a cross-sectional view of the structure 100 shown in FIG. 19 taken along line X₁-X₁, FIG. 18 depicts a cross-sectional view of the structure 100 shown in FIG. 19 taken along line X₂-X₂, and FIG. 19 depicts a cross-sectional view of the structure 100 shown in FIGS. 17 and 18 taken along line Y-Y.

First, the first sacrificial nanosheets 104 are laterally recessed to make room for the inner spacers 126. In one or more embodiments, the first sacrificial nanosheets 104 are laterally recessed using a hydrogen chloride (HCl) gas isotropic etch process, which etches silicon germanium without attacking silicon. In other embodiments, the first sacrificial nanosheets 104 are laterally recessed using a ClF3 etch process. Cavities (not shown) are formed by spaces that were occupied by the removed portions of the first sacrificial nanosheets 104.

The inner spacers 126 are formed by first conformally depositing a spacer material over the structure 100 to fill the cavities created by laterally recessing the first sacrificial nanosheets 104. The conformal spacer material is then isotropically etched to remove all portions except those remaining in the cavities and forming the inner spacers 126. In one or more embodiments, the inner spacers 126 are made from a nitride containing material, for example silicon nitride (SiN). Although inner spacers 126 shown in FIGS. 17 and 18 are formed from a nitride containing material, they can be formed from any material for which subsequent device fabrication operations are not very selective. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 126 can be selected based on a selectivity of subsequent device fabrication operations for the selected material being below a predetermined threshold.

The inner spacers 126 are positioned such that subsequent etching processes used to remove the first sacrificial nanosheets 104 during device fabrication do not also attack subsequently formed source drain regions.

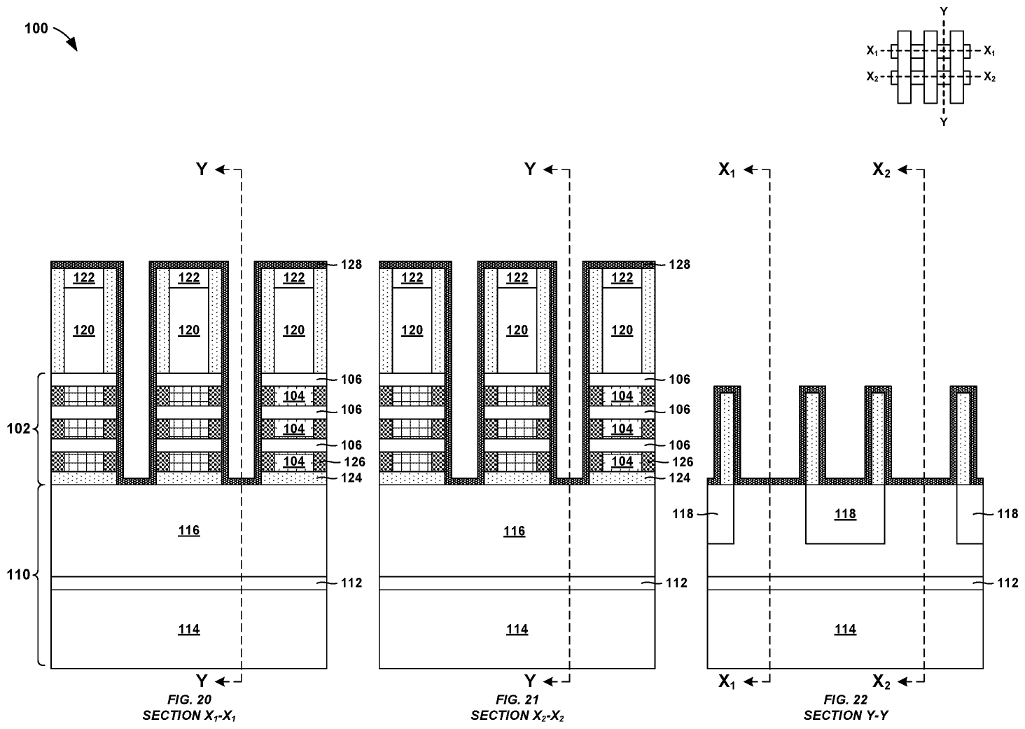

Referring now to FIGS. 20, 21, and 22, the structure 100 is shown after forming a first sacrificial liner 128 according to an embodiment of the invention. FIG. 20 depicts a cross-sectional view of the structure 100 shown in FIG. 22 taken along line X₁-X₁, FIG. 21 depicts a cross-sectional view of the structure 100 shown in FIG. 22 taken along line X₂-X₂, and FIG. 22 depicts a cross-sectional view of the structure 100 shown in FIGS. 20 and 21 along line Y-Y.

The first sacrificial liner 128 is conformally deposited directly on exposed surfaces of the structure 100 according to known techniques. Specifically, for example, a relatively thin layer of silicon nitride (SiN) is conformally deposited over and around the nanosheet stacks 102, the sacrificial gates 120, and the spacer material 124, as illustrated.

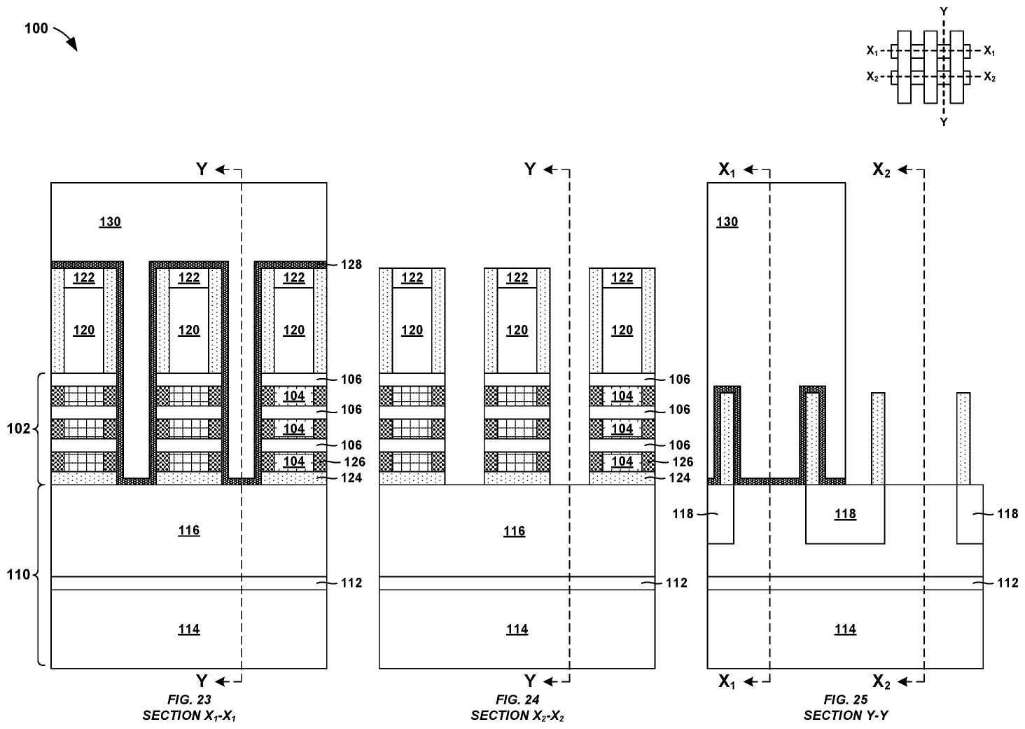

Referring now to FIGS. 23, 24, and 25, the structure 100 is shown after forming a first mask 130 and removing portions of the first sacrificial liner 128 according to an embodiment of the invention. FIG. 23 depicts a cross-sectional view of the structure 100 shown in FIG. 25 taken along line X₁-X₁, FIG. 24 depicts a cross-sectional view of the structure 100 shown in FIG. 25 taken along line X₂-X₂, and FIG. 25 depicts a cross-sectional view of the structure 100 shown in FIGS. 23 and 24 along line Y-Y.

First, the first mask 130 is deposited and subsequently patterned to expose certain portions of the structure 100 according to known techniques. Specifically, portions of the first sacrificial liner 128 in regions designated for P-type source drain regions are exposed, as illustrated in FIG. 25.

The first mask 130 can be an organic planarization layer (OPL) or a layer of material that is capable of being planarized or etched by known techniques. In an embodiment, for example, the first mask 130 can be an amorphous carbon layer able to withstand subsequent processing temperatures. The first mask 130 can preferably have a thickness sufficient to cover existing structures. After deposition of the first mask 130, a dry etching technique is applied to pattern the first mask 130 according to known techniques.

Next, the portions of the first sacrificial liner 128 in regions designated for P-type source drain regions are removed according to known techniques. Specifically, exposed portions of the first sacrificial liner 128 are removed using known etching techniques suitable to remove silicon nitride selective to the spacer material 124, the gate hard mask 122, the channel nanosheets 106, and the inner spacers 126. In an embodiment, the portions of the first sacrificial liner 128 are removed using an anisotropic etch such as, for example, reactive ion etching.

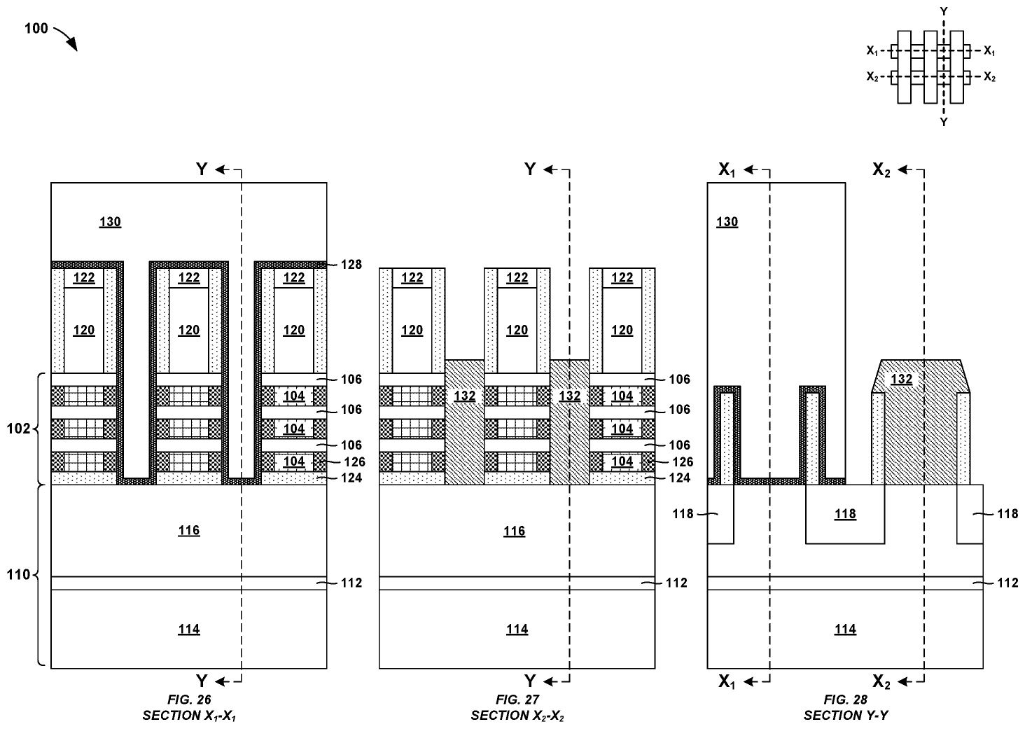

Referring now to FIGS. 26, 27, and 28, the structure 100 is shown after forming first source drain regions 132 according to an embodiment of the invention. FIG. 26 depicts a cross-sectional view of the structure 100 shown in FIG. 28 taken along line X₁-X₁, FIG. 27 depicts a cross-sectional view of the structure 100 shown in FIG. 28 taken along line X₂-X₂, and FIG. 28 depicts a cross-sectional view of the structure 100 shown in FIGS. 26 and 27 along line Y-Y.

The first source drain regions 132 are formed using an epitaxial layer growth process on the exposed ends of the channel nanosheets 106 according to known techniques. Typically, in-situ doping is used to dope the first source drain regions 132, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, the first source drain regions 132 are of a first-type, for example, P-type. As such, the first source drain regions 132 may be made from silicon geranium based epitaxy. In at least one embodiment, the first source drain regions 132 are made from silicon germanium doped with boron (B). It is critical to the present invention that the source drain epitaxy, for example the first source drain regions 132, is a different material than the top semiconductor layer 116. Doing so ensures positive etch selectivity and limits damage to the first source drain regions 132 during subsequent removal of the top semiconductor layer 116.

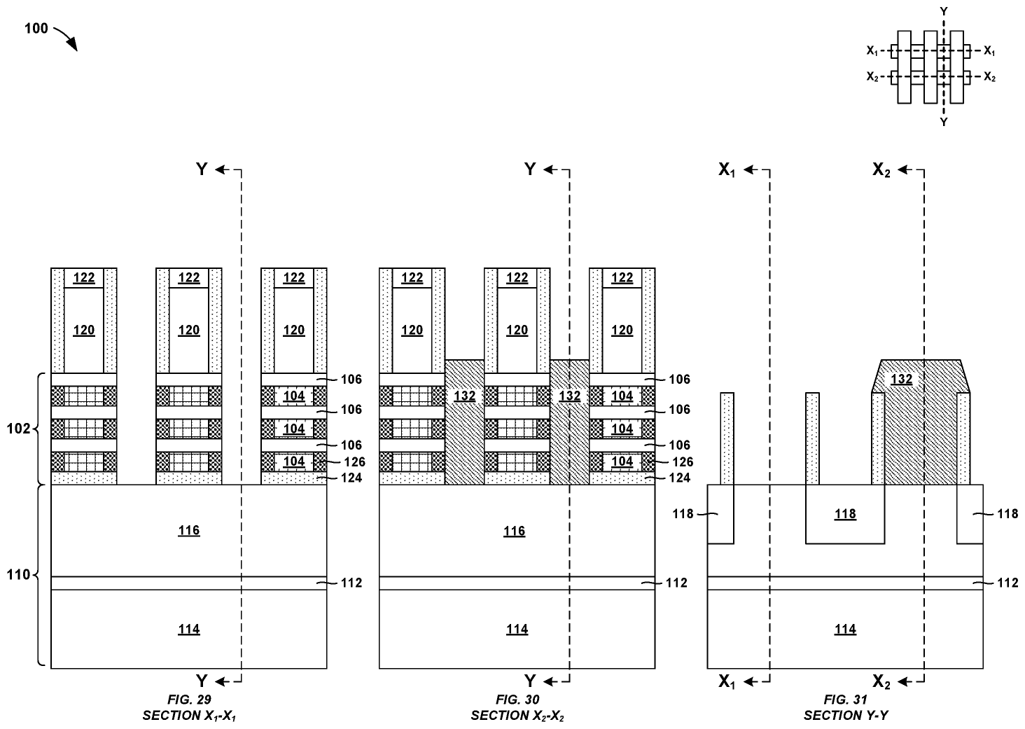

Referring now to FIGS. 29, 30, and 31, the structure 100 is shown after removing remaining portions of the first sacrificial liner 128 according to an embodiment of the invention. FIG. 29 depicts a cross-sectional view of the structure 100 shown in FIG. 31 taken along line X₁-X₁, FIG. 30 depicts a cross-sectional view of the structure 100 shown in FIG. 31 taken along line X₂-X₂, and FIG. 31 depicts a cross-sectional view of the structure 100 shown in FIGS. 29 and 30 along line Y-Y.

Next, the remaining portions of the first sacrificial liner 128 are removed according to known techniques. Specifically, remaining portions of the first sacrificial liner 128 are removed using known etching techniques suitable to remove silicon nitride selective to the spacer material 124, the gate hard mask 122, the channel nanosheets 106, and the inner spacers 126. In an embodiment, the remaining portions of the first sacrificial liner 128 are removed using an anisotropic etch such as, for example, reactive ion etching.

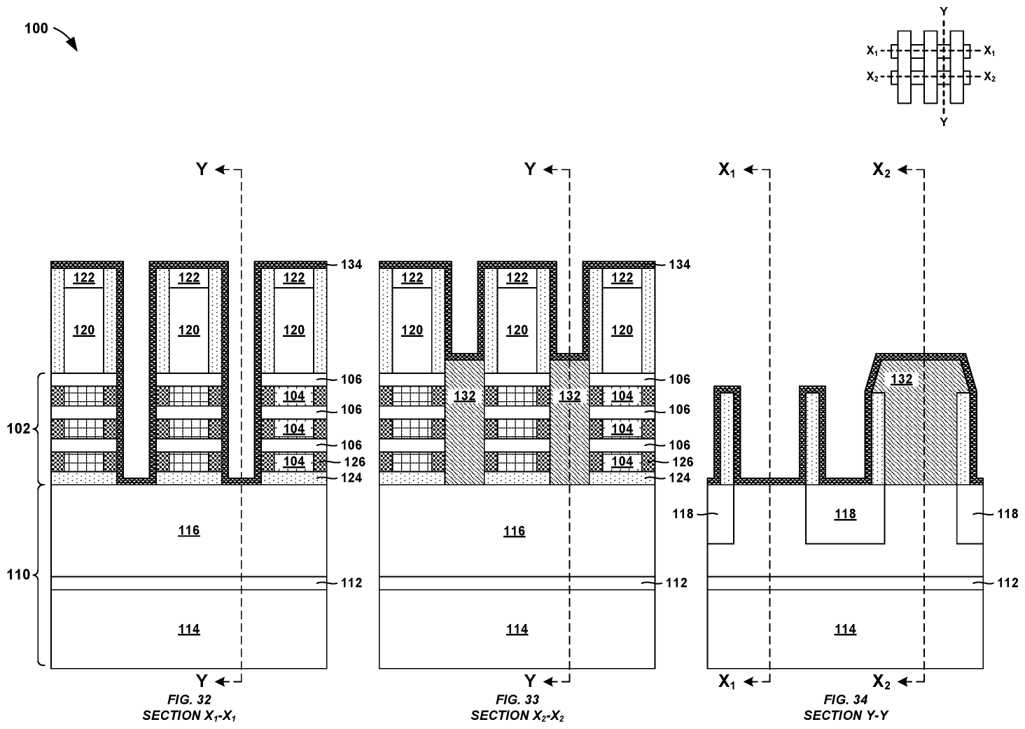

Referring now to FIGS. 32, 33, and 34, the structure 100 is shown after forming a second sacrificial liner 134 according to an embodiment of the invention. FIG. 32 depicts a cross-sectional view of the structure 100 shown in FIG. 34 taken along line X₁-X₁, FIG. 33 depicts a cross-sectional view of the structure 100 shown in FIG. 34 taken along line X₂-X₂, and FIG. 34 depicts a cross-sectional view of the structure 100 shown in FIGS. 32 and 33 along line Y-Y.

The second sacrificial liner 134 is conformally deposited directly on exposed surfaces of the structure 100 according to known techniques. Specifically, for example, a relatively thin layer of silicon nitride (SiN) is conformally deposited over and around the nanosheet stacks 102, the sacrificial gates 120, the spacer material 124, and the first source drain regions 132, as illustrated.

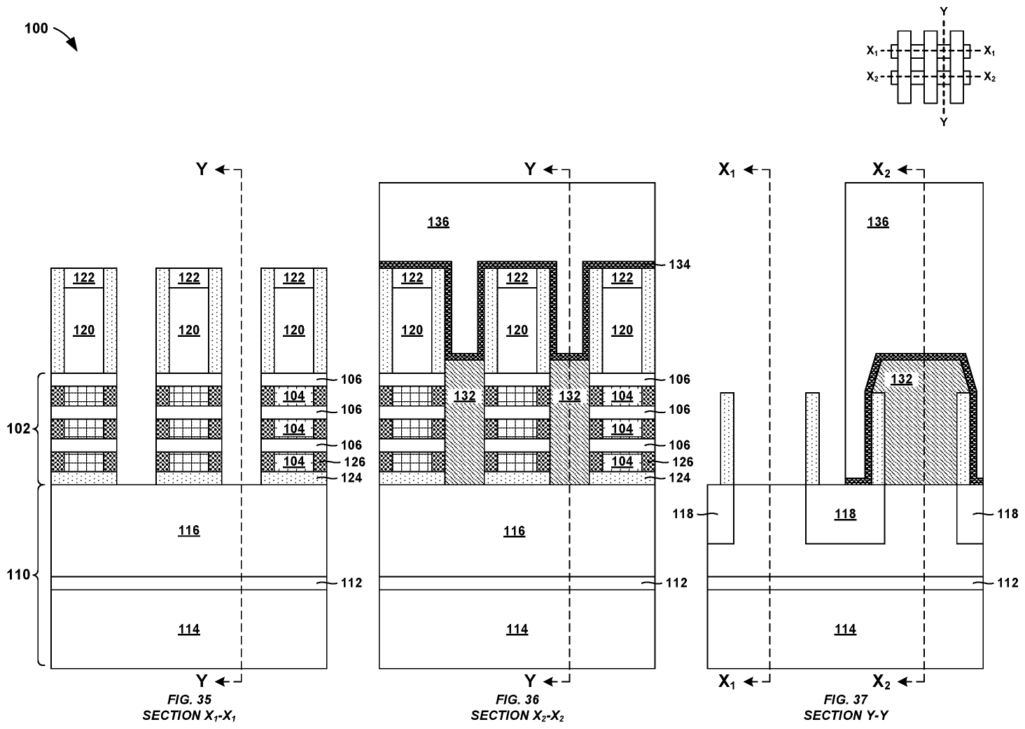

Referring now to FIGS. 35, 36, and 37, the structure 100 is shown after forming second mask 136 according to an embodiment of the invention. FIG. 35 depicts a cross-sectional view of the structure 100 shown in FIG. 37 taken along line X₁-X₁, FIG. 36 depicts a cross-sectional view of the structure 100 shown in FIG. 37 taken along line X₂-X₂, and FIG. 37 depicts a cross-sectional view of the structure 100 shown in FIGS. 35 and 36 along line Y-Y.

First, the second mask 136 is deposited and subsequently patterned to expose certain portions of the structure 100 according to known techniques. Specifically, portions of the second sacrificial liner 134 in regions designated for P-type source drain regions are exposed, as illustrated in FIG. 25.

The second mask 136 can be an organic planarization layer (OPL) or a layer of material that is capable of being planarized or etched by known techniques. In an embodiment, for example, the second mask 136 can be an amorphous carbon layer able to withstand subsequent processing temperatures. The second mask 136 can preferably have a thickness sufficient to cover existing structures. After deposition of the second mask 136, a dry etching technique is applied to pattern the second mask 136 according to known techniques.

Next, the portions of the second sacrificial liner 134 in regions designated for N-type source drain regions are removed according to known techniques. Specifically, exposed portions of the second sacrificial liner 134 are removed using known etching techniques suitable to remove silicon nitride selective to the spacer material 124, the gate hard mask 122, the channel nanosheets 106, and the inner spacers 126. In an embodiment, the portions of the second sacrificial liner 134 are removed using an anisotropic etch such as, for example, reactive ion etching.

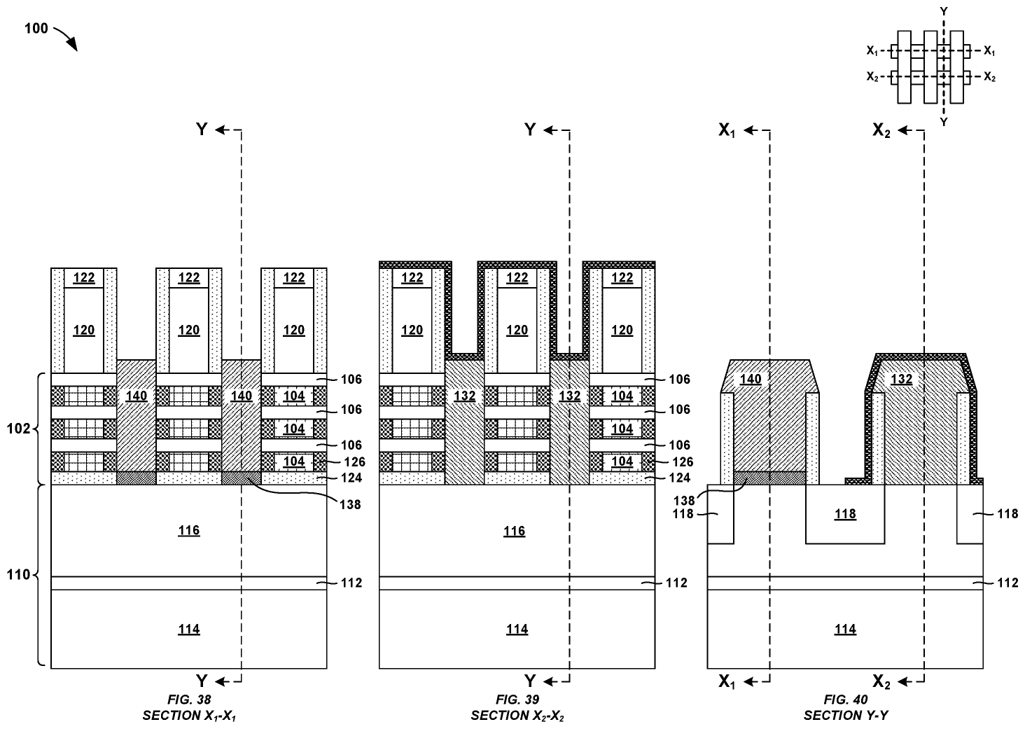

Referring now to FIGS. 38, 39, and 40, the structure 100 is shown after forming a buffer layer 138 and second source drain regions 140 according to an embodiment of the invention. FIG. 38 depicts a cross-sectional view of the structure 100 shown in FIG. 25 taken along line X₁-X₁, FIG. 39 depicts a cross-sectional view of the structure 100 shown in FIG. 25 taken along line X₂-X₂, and FIG. 40 depicts a cross-sectional view of the structure 100 shown in FIGS. 23 and 24 along line Y-Y.

First, the buffer layer 138 is formed in the regions designated for N-type source drain regions according to known techniques and as illustrated. Specifically, the buffer layer 138 is epitaxially grown directly on top of exposed portions of the substrate 110 between adjacent nanosheet stacks 102, as illustrated.

Next, the second source drain regions 140 are formed using an epitaxial layer growth process on the exposed ends of the channel nanosheets 106 according to known techniques. Typically, in-situ doping is used to dope the second source drain regions 140, thereby creating the necessary junctions of the semiconductor device. According to embodiments of the present invention, the second source drain regions 140 are of a second-type, for example, N-type. As such, the second source drain regions 140 may be made from silicon based epitaxy. In at least one embodiment, the second source drain regions 140 are made from silicon doped with arsenic (As) or phosphorous (P).

As previously indicated, it is critical to the present invention that the source drain epitaxy be a different material than the top semiconductor layer 116; however, if N-type source drain regions, for example the second source drain regions 140, were made from silicon germanium, as an example, N-type device performance suffers. Therefore, the second source drain regions 140 cannot be silicon germanium to offer the desired etch selectivity. Also, without the buffer layer 138, the second source drain regions 140 cannot be the same material as the top semiconductor layer 116 (e.g. silicon) because there will be no etch selectivity between the second source drain regions 140 and the top semiconductor layer 116. As such, the buffer layer 138 provides the necessary separation between the second source drain regions 140 and the top semiconductor layer 116. According to embodiments of the present invention, the buffer layer 138 can be made from silicon germanium which has good etch selectivity to both the optimal materials of the second source drain regions 140 (e.g. silicon) and the top semiconductor layer 116.

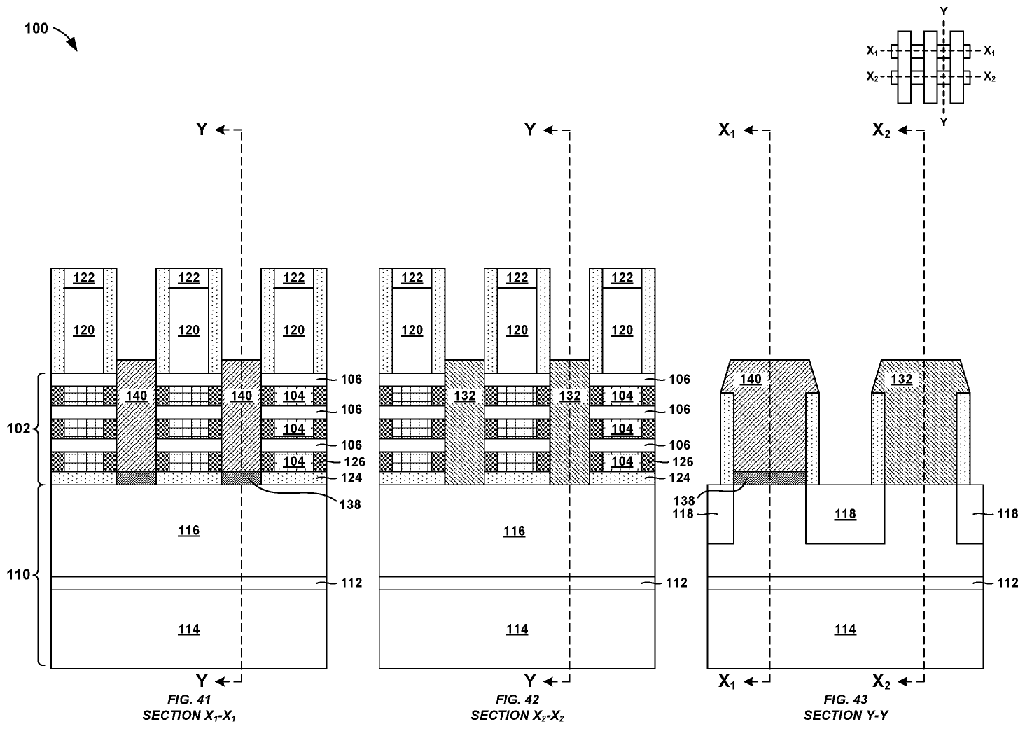

Referring now to FIGS. 41, 42, and 43, the structure 100 is shown after removing remaining portions of the second sacrificial liner 134 according to an embodiment of the invention. FIG. 41 depicts a cross-sectional view of the structure 100 shown in FIG. 43 taken along line X₁-X₁, FIG. 42 depicts a cross-sectional view of the structure 100 shown in FIG. 43 taken along line X₂-X₂, and FIG. 43 depicts a cross-sectional view of the structure 100 shown in FIGS. 41 and 42 along line Y-Y.

Next, the remaining portions of the second sacrificial liner 134 are removed according to known techniques. Specifically, remaining portions of the second sacrificial liner 134 are removed using known etching techniques suitable to remove silicon nitride selective to the spacer material 124, the gate hard mask 122, the channel nanosheets 106, and the inner spacers 126. In an embodiment, the remaining portions of the second sacrificial liner 134 are removed using an anisotropic etch such as, for example, reactive ion etching.

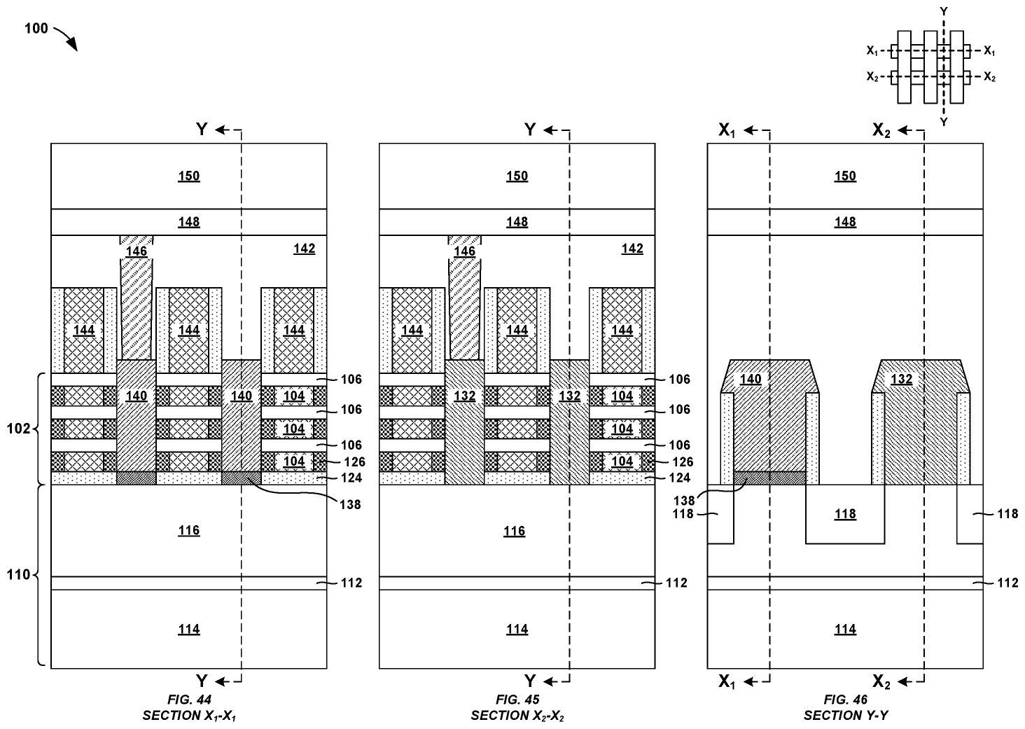

Referring now to FIGS. 44, 45, and 46, the structure 100 is shown after forming a dielectric layer 142, selectively removing the sacrificial gates 120 and the first sacrificial nanosheets 104, forming gate structures 144, forming source drain contacts 146, forming middle-of-line and back-end-of-line 148 and securing a carrier wafer 150 according to an embodiment of the invention. FIG. 44 depicts a cross-sectional view of the structure 100 shown in FIG. 46 taken along line X₁-X₁, FIG. 45 depicts a cross-sectional view of the structure 100 shown in FIG. 46 taken along line X₂-X₂, and FIG. 46 depicts a cross-sectional view of the structure 100 shown in FIGS. 44 and 45 along line Y-Y.

The dielectric layer 142 is formed by blanket depositing an interlayer dielectric material over the structure 100 according to known techniques. Specifically, the dielectric layer 142 is formed on the first source drain regions 132 and second source drain regions 140 and substantially fills the remaining space between the spacer material 124, as illustrated.

The dielectric layer 142 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 142. Using a self-planarizing dielectric material as the dielectric layer 142 can avoid the need to perform a subsequent planarizing step.

After the dielectric layer 142 is formed, the structure is polished according to known techniques, such as, for example, chemical mechanical polishing techniques. Specifically, the dielectric layer 142, the spacer material 124, and the gate hard mask 122 are polished until a topmost surface of the dielectric layer 142 is flush, or substantially flush, with topmost surfaces of the spacer material 124 and the sacrificial gates 120.

Next, the sacrificial gates 120 and the first sacrificial nanosheets 104 are selectively removed according to known techniques.

First, the sacrificial gates 120 are etched and removed selective to the spacer material 124 and the nanosheet stacks 102 according to known techniques. Next, the first sacrificial nanosheets 104 are etched and removed selective to the channel nanosheets 106 and the inner spacers 126 according to known techniques. Doing so is made possible by the different concentrations of germanium. In this case, the layers with germanium are removed selective to layers without germanium.

Next, the gate structures 144 are formed according to known techniques. First, a gate dielectric (not shown) is conformally deposited directly on exposed surfaces of the structure 100 within the gate cavities or openings and spaces left by removing the sacrificial gates 120 and the first sacrificial nanosheets 104 according to known techniques. For example, the gate dielectric is conformally deposited on exposed surfaces of the channel nanosheets 106 and the inner spacers 126.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, a work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, gate metal or contact metal, is deposited directly on the work function metal, and fills the gate cavities. The first gate metal may include any suitable conductive material, such as, for example, copper, ruthenium, aluminum, tungsten, cobalt, or alloys thereof. After, excess conductive material can be polished using known techniques.

Finally, additional interlayer dielectric material is deposited according to known techniques. The dielectric layer 142 illustrated in the figures includes the additional interlayer dielectric material.

With continued reference to FIGS. 44, 45, and 46, the structure 100 is shown after forming the source drain contacts 146, forming the middle-of-line and back-end-of-line 148, and attaching the carrier wafer 150 according to an embodiment of the invention

Next, portions of the dielectric layer 142 are removed to expose the source drain regions 132, 140. Next, the openings are filled with a conductive material to form the source drain contacts 146 according to known techniques. The source drain contacts 146 may include any suitable conductive material, such as, for example, copper, ruthenium, aluminum, tungsten, cobalt, or alloys thereof. In some embodiments, a metal silicide is formed at the bottom of the contact trenches prior to filling them with the conductive material. In some embodiments, the source drain contacts 146 do not contact the spacer material 124. In other embodiments, the source drain contacts 146 are self-aligned to the spacer material 124, and thus may be referred to as self-aligned contact structures.

Finally, the middle-of-line and back-end-of-line 148 (hereinafter MOL/BEOL 148) is formed and carrier wafer 150 is secured to a top of the structure 100 according to an embodiment of the invention. After forming the source drain contacts 146, the MOL/BEOL 148 is subsequently formed according to known techniques. Next, the carrier wafer 150 is attached, or removably secured, to the MOL/BEOL 148. In general, and not depicted, the carrier wafer 150 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 150 according to known techniques.

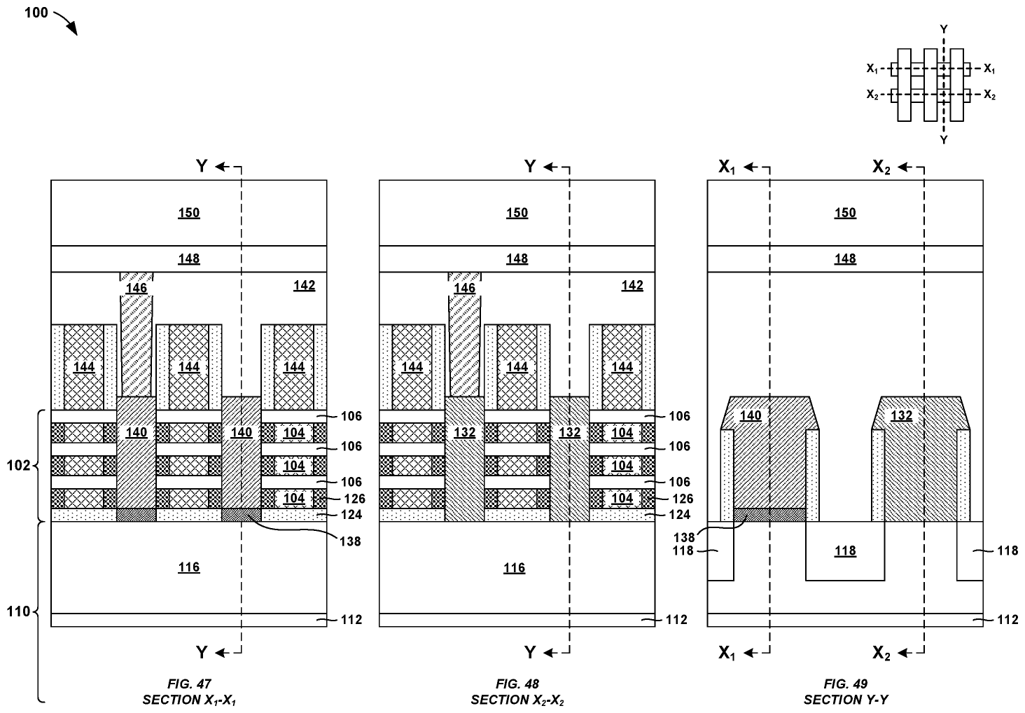

Referring now to FIGS. 47, 48, and 49, the structure 100 is shown after flipping the assembly and recessing the substrate 110 according to an embodiment of the invention. FIG. 47 depicts a cross-sectional view of the structure 100 shown in FIG. 49 taken along line X₁-X₁, FIG. 48 depicts a cross-sectional view of the structure 100 shown in FIG. 49 taken along line X₂-X₂, and FIG. 49 depicts a cross-sectional view of the structure 100 shown in FIGS. 47 and 48 along line Y-Y.

First, the structure 100 is flipped 180 degrees to prepare for backside processing. In general, backside processing includes fabrication or processing of the structure 100 opposite the active device and wiring layers. Next, the substrate 110 is recessed according to known techniques. Specifically, the base substrate 114 is recessed or completely removed to expose the etch stop layer 112, as shown.

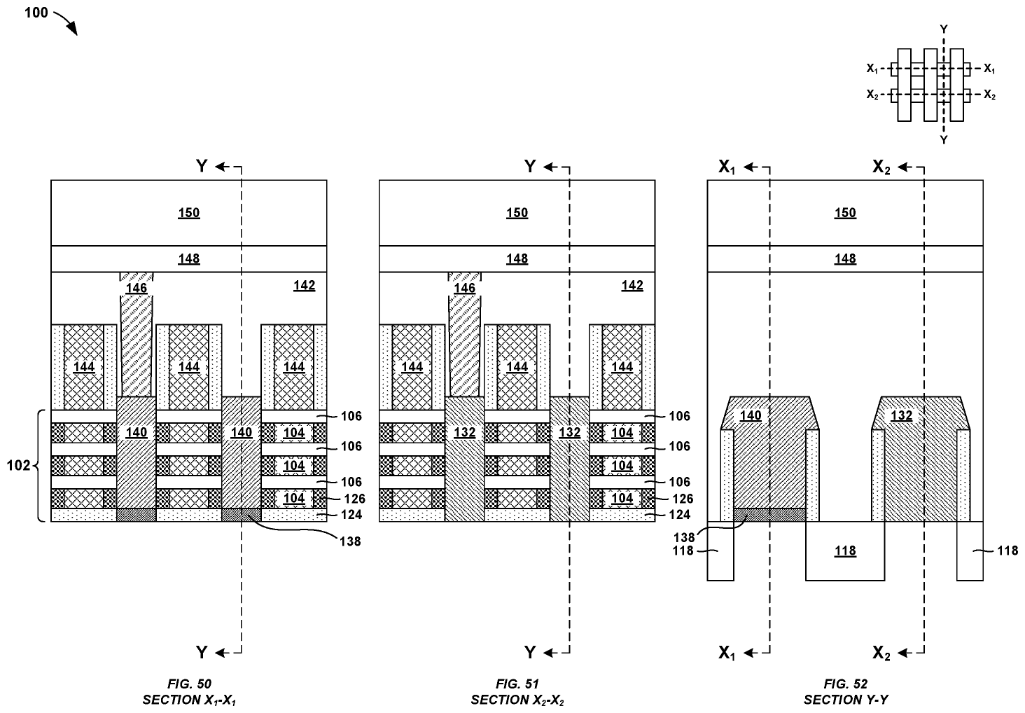

Referring now to FIGS. 50, 51, and 52, the structure 100 is shown after removing remaining portions of the substrate 110 according to an embodiment of the invention. FIG. 50 depicts a cross-sectional view of the structure 100 shown in FIG. 52 taken along line X₁-X₁, FIG. 51 depicts a cross-sectional view of the structure 100 shown in FIG. 52 taken along line X₂-X₂, and FIG. 52 depicts a cross-sectional view of the structure 100 shown in FIGS. 50 and 51 taken along line Y-Y.

First, the etch stop layer 112 and the top semiconductor layer 116 are selectively removed according to known techniques. Specifically, the etch stop layer 112 is removed selective to the top semiconductor layer 116 and the top semiconductor layer 116 is removed selective to the first source drain regions 132 and the buffer layer 138. Unique to the disclosed embodiments, the second source drain regions 140 remains damage free during removal of the substrate 110 due to the existence of the buffer layer 138.

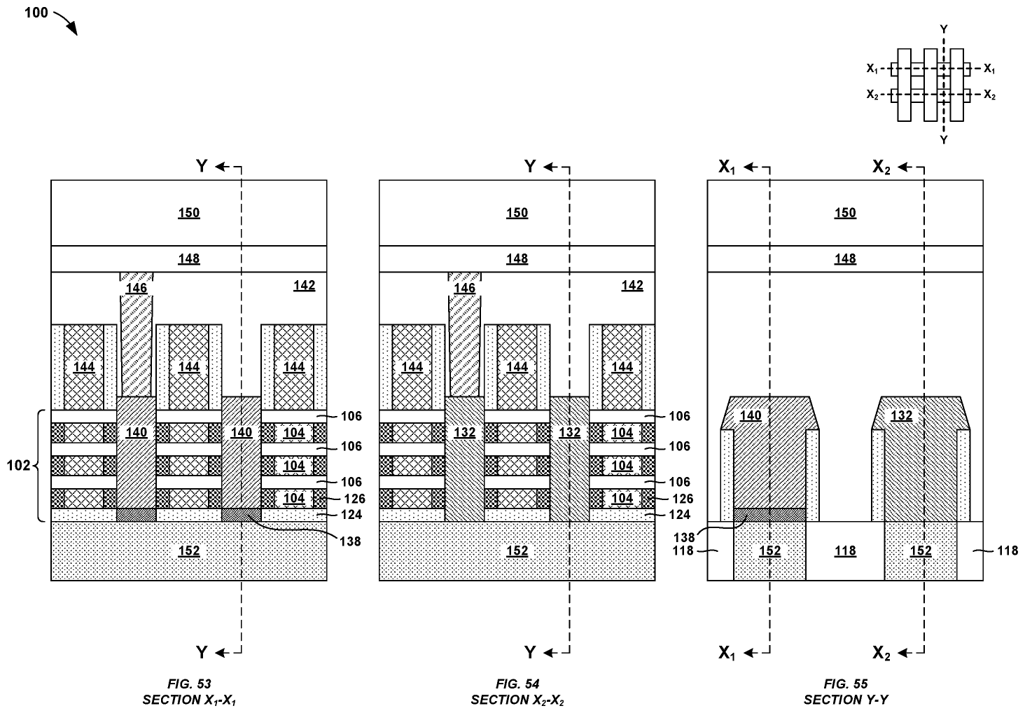

Referring now to FIGS. 53, 54, and 55, the structure 100 is shown after forming a backside dielectric layer 152 according to an embodiment of the invention. FIG. 53 depicts a cross-sectional view of the structure 100 shown in FIG. 55 taken along line X₁-X₁, FIG. 54 depicts a cross-sectional view of the structure 100 shown in FIG. 55 taken along line X₂-X₂, and FIG. 55 depicts a cross-sectional view of the structure 100 shown in FIGS. 53 and 54 taken along line Y-Y.

The backside dielectric layer 152 is formed by blanket depositing an interlayer dielectric material over the structure 100 according to known techniques. Specifically, the backside dielectric layer 152 is formed on the first source drain regions 132 and second source drain regions 140 and the spacer material 124, as illustrated.

The backside dielectric layer 152 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the backside dielectric layer 152. Using a self-planarizing dielectric material as the backside dielectric layer 152 can avoid the need to perform a subsequent planarizing step.

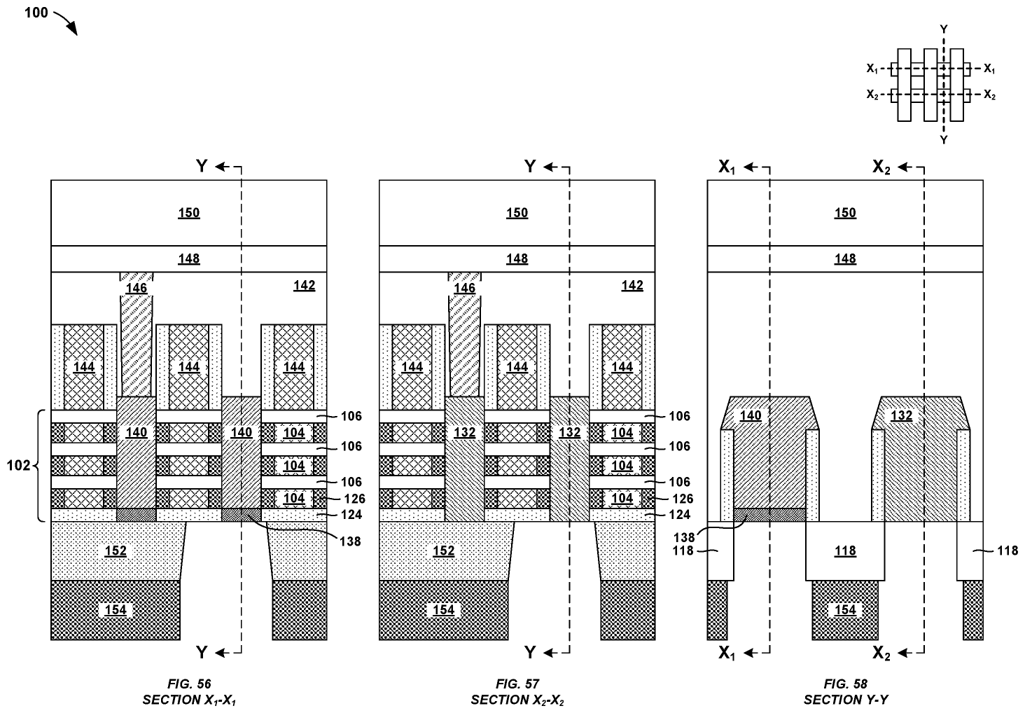

Referring now to FIGS. 56, 57, and 58, the structure 100 is shown after forming a second mask 154 and backside contact trenches 156 according to an embodiment of the invention. FIG. 56 depicts a cross-sectional view of the structure 100 shown in FIG. 58 taken along line X₁-X₁, FIG. 57 depicts a cross-sectional view of the structure 100 shown in FIG. 58 taken along line X₂-X₂, and FIG. 58 depicts a cross-sectional view of the structure 100 shown in FIGS. 56 and 57 taken along line Y-Y.

First, the second mask 154 is deposited and subsequently patterned to expose certain portions of the structure 100 according to known techniques. The second mask 154 can be an organic planarization layer (OPL) or a layer of material that is capable of being planarized or etched by known techniques. In an embodiment, for example, the second mask 154 can be an amorphous carbon layer able to withstand subsequent processing temperatures. The second mask 154 can preferably have a thickness sufficient to cover existing structures. After deposition of the second mask 154, a dry etching technique is applied to pattern the second mask 154 according to known techniques.

Next, according to an exemplary embodiment, RIE is used to transfer the second mask 154 pattern into the backside dielectric layer 152 according to known techniques and as illustrated.

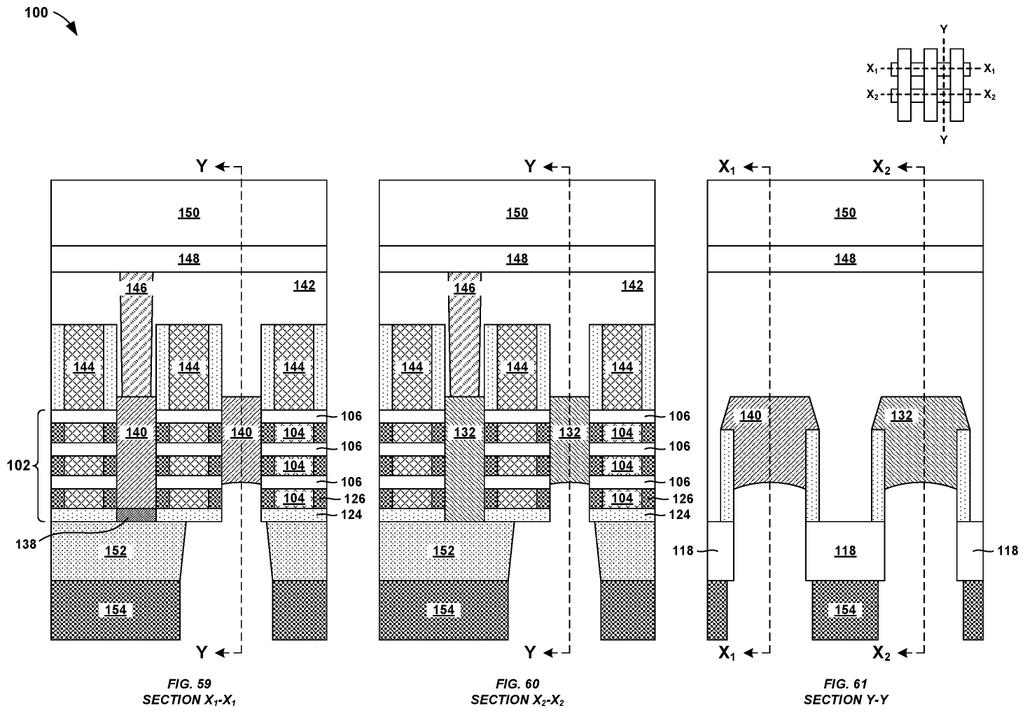

Referring now to FIGS. 59, 60, and 61, the structure 100 is shown after recessing or removing the buffer layer 138 according to an embodiment of the invention. FIG. 59 depicts a cross-sectional view of the structure 100 shown in FIG. 61 taken along line X₁-X₁, FIG. 60 depicts a cross-sectional view of the structure 100 shown in FIG. 61 taken along line X₂-X₂, and FIG. 61 depicts a cross-sectional view of the structure 100 shown in FIGS. 59 and 60 taken along line Y-Y.

The buffer layer 138 is recessed or removed according to known techniques. Specifically, the buffer layer 138 is etched to exposed the second source drain regions 140. In doing so, some of the first source drain regions 132 will also be recessed or etched. As described above with respect to at least one embodiment, both the buffer layer 138 and the first source drain regions 132 are made from silicon germanium and will etch similarly. In all cases, both the buffer layer 138 and the first source drain regions 132 are preferably made from a similar material with similar etch rates. It is possible to build the structure 100 with a buffer layer 138 made from a different material than the first source drain regions 132; however, it is preferable those two different materials will have similar etch properties and similar etch rates. Different materials with different etch properties may require multiple etch chemistries to achieve the desire structure.

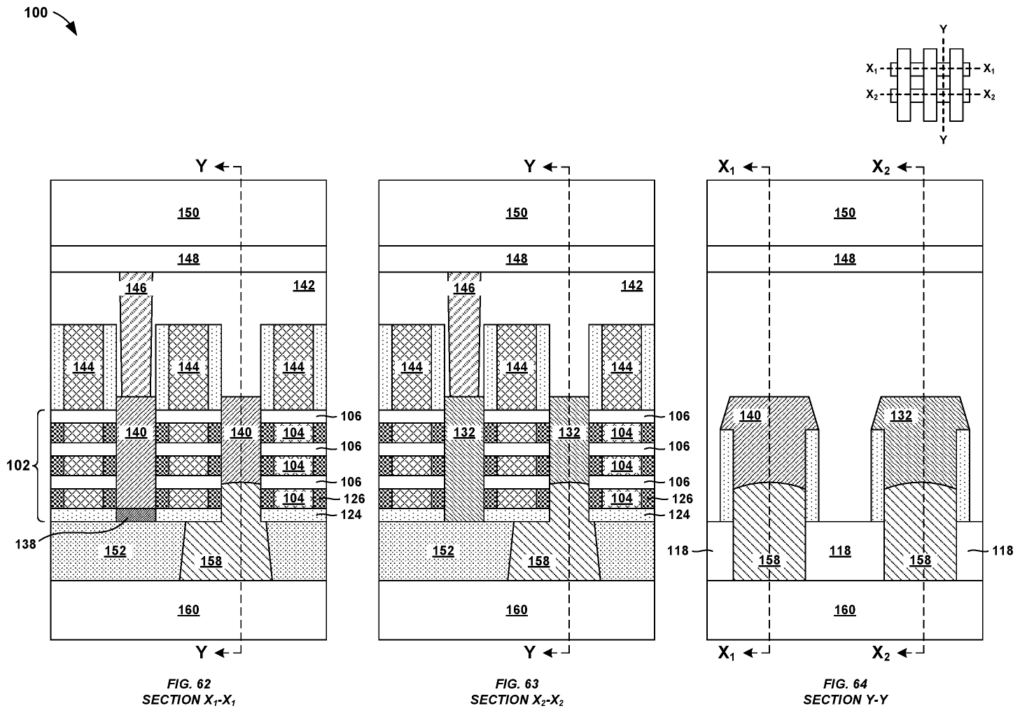

Referring now to FIGS. 62, 63, and 64, the structure 100 is shown after forming backside contact structures 158 and backside wiring layers 160 according to an embodiment of the invention. FIG. 62 depicts a cross-sectional view of the structure 100 shown in FIG. 64 taken along line X₁-X₁, FIG. 63 depicts a cross-sectional view of the structure 100 shown in FIG. 64 taken along line X₂-X₂, and FIG. 64 depicts a cross-sectional view of the structure 100 shown in FIGS. 62 and 63 taken along line Y-Y.

The backside trenches 156 are then filled with a conductive material to form the backside contact structures 158 according to known techniques. The backside contact structures 158 may include any suitable conductive material, such as, for example, copper, ruthenium, aluminum, tungsten, cobalt, or alloys thereof. In some embodiments, a metal silicide is formed at the bottom of the backside trenches 156 prior to filling them with the conductive material. After, excess conductive material can be polished using known techniques until bottommost surfaces of the backside contact structures 158 are flush, or substantially flush, with bottommost surfaces of the STI regions 118 and the backside dielectric layer 152, as illustrated. After forming the backside contact structures 158, the backside wiring layers 160 are subsequently formed according to known techniques. It is noted, the backside contact structures 158 may include, for example, backside source drain contacts, as illustrated, as well as backside gate contacts.

With continued reference to FIGS. 62, 63, and 64, and according to an embodiment, the structure 100 includes first source drain regions 132 and second source drain regions 140 arranged above a backside dielectric layer 152, and a buffer layer 138 physically separating at least one of the second source drain regions 132 from the backside dielectric layer 152, where at least one of the first source drain regions 132 is in direct contact with the backside dielectric layer 152.

With continued reference to FIGS. 62, 63, and 64, and according to an embodiment, the first source drain regions 132 are made from silicon geranium based epitaxy, and the second source drain regions 140 are made from silicon based epitaxy.

With continued reference to FIGS. 62, 63, and 64, and according to an embodiment, the buffer layer 138 and the first source drain regions 132 comprise silicon germanium.

With continued reference to FIGS. 62, 63, and 64, and according to an embodiment, the backside dielectric layer 152 is made from a different dielectric material than shallow trench isolation regions 118.

With continued reference to FIGS. 62, 63, and 64, and according to an embodiment, a width of the buffer layer 138 is substantially equal to a width of the second source drain region 140.

With continued reference to FIGS. 62, 63, and 64, and according to an embodiment, the structure further includes a first contact (158) embedded in the backside dielectric layer 152 and in direct contact with at least another one of the first source drain regions 132, a second contact (158) embedded in the backside dielectric layer 152 and in direct contact with at least another one of the second source drain regions 140.

With continued reference to FIGS. 62, 63, and 64, and according to an embodiment, the structure further includes a first contact (158) embedded in the backside dielectric layer 152 and in direct contact with at least another one of the first source drain regions 132, where a width of a first portion of the first contact (158) is substantially equal to a width of the at least another one of the first source drain regions 132, and, where a width of a second portion of the first contact (158) is greater than the width of the at least another one of the first source drain regions 132, and a second contact (158) embedded in the backside dielectric layer 152 and in direct contact with at least another one of the second source drain regions 140, where a width of a first portion of the second contact (158) is substantially equal to a width of the at least another one of the first source drain regions 132, and where a width of a second portion of the second contact (158) is greater than the width of the at least another one of the second source drain regions 140.

With continued reference to FIGS. 62, 63, and 64, and according to an embodiment, the structure 100 includes first source drain regions 132 and second source drain regions 140 arranged above a backside dielectric layer 152, a buffer layer 138 physically separating at least one of the second source drain regions 140 from the backside dielectric layer 152, where at least one of the first source drain regions 132 is in direct contact with the backside dielectric layer 152, and a bottom dielectric isolation layer physically separating nanosheet stacks from the backside dielectric layer.

With continued reference to FIGS. 62, 63, and 64, and according to an embodiment, the structure 100 includes first source drain regions 132 between a first set of adjacent nanosheet channels (106), second source drain regions (140) between a second set of adjacent nanosheet channels (106), a backside dielectric layer 152 arranged below all of the first source drain regions 132 and the second source drain regions 140, and a buffer layer 138 physically separating at least one of the second source drain regions 140 from the backside dielectric layer 152, where at least one of the first source drain regions 132 is in direct contact with the backside dielectric layer 152.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
first source drain regions and second source drain regions arranged above a backside dielectric layer; and
a buffer layer physically separating at least one of the second source drain regions from the backside dielectric layer, wherein at least one of the first source drain regions is in direct contact with the backside dielectric layer.

2. The semiconductor structure according to claim 1, wherein
the first source drain regions are made from silicon geranium based epitaxy; and
the second source drain regions are made from silicon based epitaxy.

3. The semiconductor structure according to claim 1, wherein the buffer layer and the first source drain regions comprise silicon germanium.

4. The semiconductor structure according to claim 1, wherein the backside dielectric layer is made from a different dielectric material than shallow trench isolation regions.

5. The semiconductor structure according to claim 1, wherein a width of the buffer layer is substantially equal to a width of the second source drain region.

6. The semiconductor structure according to claim 1, further comprising:
a first contact embedded in the backside dielectric layer and in direct contact with at least another one of the first source drain regions; and
a second contact embedded in the backside dielectric layer and in direct contact with at least another one of the second source drain regions.

7. The semiconductor structure according to claim 1, further comprising:
a first contact embedded in the backside dielectric layer and in direct contact with at least another one of the first source drain regions, wherein a width of a first portion of the first contact is substantially equal to a width of the at least another one of the first source drain regions, and, wherein a width of a second portion of the first contact is greater than the width of the at least another one of the first source drain regions; and
a second contact embedded in the backside dielectric layer and in direct contact with at least another one of the second source drain regions, wherein a width of a first portion of the second contact is substantially equal to a width of the at least another one of the first source drain regions, and, wherein a width of a second portion of the second contact is greater than the width of the at least another one of the second source drain regions.

8. A semiconductor structure comprising:
first source drain regions and second source drain regions arranged above a backside dielectric layer;
a buffer layer physically separating at least one of the second source drain regions from the backside dielectric layer, wherein at least one of the first source drain regions is in direct contact with the backside dielectric layer; and
a bottom dielectric isolation layer physically separating nanosheet stacks from the backside dielectric layer.

9. The semiconductor structure according to claim 8, wherein
the first source drain regions are made from silicon geranium based epitaxy; and
the second source drain regions are made from silicon based epitaxy.

10. The semiconductor structure according to claim 8, wherein the buffer layer and the first source drain regions comprise silicon germanium.

11. The semiconductor structure according to claim 8, wherein the backside dielectric layer is made from a different dielectric material than shallow trench isolation regions.

12. The semiconductor structure according to claim 8, wherein a width of the buffer layer is substantially equal to a width of the second source drain region.

13. The semiconductor structure according to claim 8, further comprising:
a first contact embedded in the backside dielectric layer and in direct contact with at least another one of the first source drain regions, wherein a width of a first portion of the first contact is substantially equal to a width of the at least another one of the first source drain regions, and, wherein a width of a second portion of the first contact is greater than the width of the at least another one of the first source drain regions; and
a second contact embedded in the backside dielectric layer and in direct contact with at least another one of the second source drain regions, wherein a width of a first portion of the second contact is substantially equal to a width of the at least another one of the first source drain regions, and, wherein a width of a second portion of the second contact is greater than the width of the at least another one of the second source drain regions.

14. A semiconductor structure comprising:
first source drain regions between a first set of adjacent nanosheet channels;
second source drain regions between a second set of adjacent nanosheet channels;
a backside dielectric layer arranged below all of the first source drain regions and the second source drain regions; and
a buffer layer physically separating at least one of the second source drain regions from the backside dielectric layer, wherein at least one of the first source drain regions is in direct contact with the backside dielectric layer.

15. The semiconductor structure according to claim 14, wherein
the first source drain regions are made from silicon geranium based epitaxy; and
the second source drain regions are made from silicon based epitaxy.

16. The semiconductor structure according to claim 1, wherein the buffer layer and the first source drain regions comprise silicon germanium.

17. The semiconductor structure according to claim 14, wherein the backside dielectric layer is made from a different dielectric material than shallow trench isolation regions.

18. The semiconductor structure according to claim 14, wherein a width of the buffer layer is substantially equal to a width of the second source drain region.

19. The semiconductor structure according to claim 14, further comprising:
a first contact embedded in the backside dielectric layer and in direct contact with at least another one of the first source drain regions; and
a second contact embedded in the backside dielectric layer and in direct contact with at least another one of the second source drain regions.

20. The semiconductor structure according to claim 14, further comprising:
a first contact embedded in the backside dielectric layer and in direct contact with at least another one of the first source drain regions, wherein a width of a first portion of the first contact is substantially equal to a width of the at least another one of the first source drain regions, and, wherein a width of a second portion of the first contact is greater than the width of the at least another one of the first source drain regions; and
a second contact embedded in the backside dielectric layer and in direct contact with at least another one of the second source drain regions, wherein a width of a first portion of the second contact is substantially equal to a width of the at least another one of the first source drain regions, and, wherein a width of a second portion of the second contact is greater than the width of the at least another one of the second source drain regions.
